(19) United States
(12) Patent Application Publication
(10) Pub. No.: US 2026/0221962 A1
(43) Pub. Date: Jul. 30, 2026

(54) COMPARATOR CIRCUIT PROVIDED WITH MOS TRANSISTORS USED AS DIFFERENTIAL PAIR, AND POWER SUPPLY APPARATUS WITH THE COMPARATOR CIRCUIT

(71) Applicant: NISSHINBO MICRO DEVICES INC., Tokyo (JP)

(72) Inventors: Junki Tsuboi, Tokyo (JP); Atsushi Nishii, Tokyo (JP); Daisuke Kanzaki, Tokyo (JP)

(21) Appl. No.: 19/142,777

(22) PCT Filed: Jan. 31, 2023
(86) PCT No.: PCT/JP2023/003068

§ 371 Date: Jun. 24, 2025

(51) Int. Cl. H03K 5/24; H02J 7/50; H02J 7/60

(52) U.S. Cl. CPC H03K 5/2481; H02J 7/50; H02J 7/60

(57) ABSTRACT

A comparator circuit includes a comparator, which detects an abnormal voltage of a secondary battery, and uses PMOS transistors or NMOS transistors used as a differential pair. The comparator circuit includes a control circuit that is configured to control voltages of two input terminals of the comparator are to be equal to each other in a standby state in which an operation of the comparator circuit is in a stop state.

### TECHNICAL FIELD

The present invention relates to a comparator circuit using, for example, P-channel MOS transistors (hereinafter, referred to as PMOS transistors) or N-channel MOS transistors (hereinafter, it is referred to as NMOS transistors) which are used as a differential pair, and a power supply apparatus using the comparator circuit.

### BACKGROUND ART

Conventionally, in a comparator circuit using PMOS transistors as a differential pair, various techniques for preventing characteristic deterioration due to negative bias temperature instability (NBTI) have been disclosed.

When the chip temperature rises in a state where the substrate potential is negative with respect to the gate electrode of the PMOS transistor, the absolute value of the threshold voltage of the PMOS transistor gradually increases, and the characteristics (Ids, Vth) of the PMOS transistor fluctuate. In this case, in a state where a negative bias voltage is applied, a phenomenon in which degradation of the element progresses regardless of the operation of the PMOS transistor is referred to as NBTI. In particular, characteristic degradation occurs by varying the threshold in a state where the drain voltage is higher than the gate voltage.

For example, Patent Document 1 proposes a comparator circuit according to a conventional example for easily suppressing an increase in a drain voltage of PMOS transistors configuring a differential pair. The comparator circuit includes first and second PMOS transistors configuring a differential pair, a first switching transistor having a main current path connected between an input terminal and a gate of the first PMOS transistor, a voltage source that applies a reference voltage to the gate of the second PMOS transistor, and a first bias circuit that applies a first bias voltage to a control electrode of the first switching transistor.

### PRIOR ART DOCUMENT

### PATENT DOCUMENT

Patent Document 1: Japanese Patent Laid-open Publication No. JP2020-120320A.

### SUMMARY OF THE INVENTION

### PROBLEMS TO BE SOLVED BY THE INVENTION

In a battery voltage monitoring circuit including the comparator circuit according to the above-described conventional example, an input potential difference of the comparator circuit is likely to occur, and occurrence of NBTI cannot be suppressed in a state where the operation of the reference voltage circuit is stopped. In particular, it is conceivable that a protection circuit of a lithium battery is in a standby state for a long time in a factory shipment mode or the like, and at that time, the reference voltage circuit is stopped and NBTI occurs. It is noted that in a comparator circuit using an NMOS transistor as a differential pair, characteristic degradation due to positive bias temperature instability (PBTI) occurs similarly to the NBTI.

An object of the present invention is to solve the above problems, and to provide a comparator circuit that can suppress the occurrence of NBTI or PBTI without depending on an input potential difference of the comparator circuit in the comparator circuit using a PMOS transistor or an NMOS transistor as a differential pair, and a power supply apparatus using the comparator circuit.

### SOLUTIONS TO THE PROBLEMS

According to one aspect of the present invention, there is provided a comparator circuit including a comparator for detecting an abnormal voltage of a secondary battery. The comparator uses a PMOS transistor or an NMOS transistor as a differential pair, and the comparator circuit includes a control circuit configured to control voltages at two input terminals of the comparator to be equal to each other in a standby state that is a circuit operation stop state of the comparator circuit.

### EFFECTS OF THE INVENTION

Therefore, according to the comparator circuit according to one aspect of the present invention, in the comparator circuit using the PMOS transistors or the NMOS transistors as the differential pair, it is possible to suppress the occurrence of NBTI or PBTI without depending on the input potential difference of the comparator circuit.

### BRIEF DESCRIPTION OF THE DRAWINGS

FIG. 1 is a circuit diagram illustrating a configuration example of a comparator circuit according to a first embodiment.

FIG. 2 is a circuit diagram illustrating a configuration example of a comparator circuit according to a second embodiment.

FIG. 3 is a circuit diagram illustrating a configuration example of a power supply apparatus using a comparator circuit according to a third embodiment.

FIG. 4 is a circuit diagram illustrating a configuration example of a power supply apparatus using a comparator circuit according to a fourth embodiment.

FIG. 5 is a circuit diagram illustrating a configuration example of a power supply apparatus using a standby control circuit according to a fifth embodiment.

FIG. 6 is a circuit diagram illustrating a configuration of a comparator circuit according to a comparison example.

FIG. 7 is a circuit diagram illustrating a configuration of a comparator circuit according to a comparison example.

FIG. 8 is a circuit diagram illustrating a known configuration of a comparator circuit according to a comparison example.

### DETAILED DESCRIPTION

Hereinafter, embodiments and modified embodiments according to the present invention will be described with reference to the drawings. It is noted that the same or similar components are denoted by the same reference numerals.

### FINDINGS OF INVENTORS

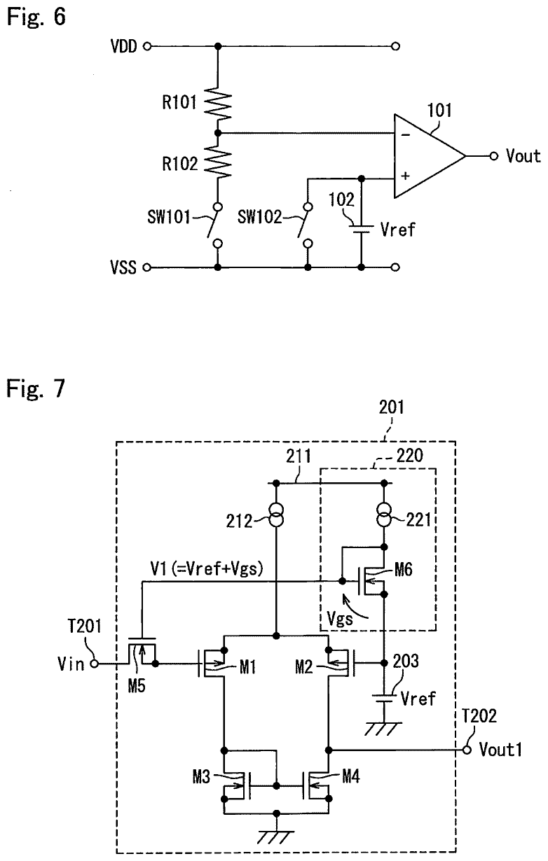

FIG. 6 is a circuit diagram illustrating a configuration of a comparator circuit according to a comparison example. The comparator circuit of FIG. 6 is used in, for example, an abnormal voltage detector circuit used in a lithium battery protection IC, and includes a comparator 101 using PMOS transistors as a differential pair as in Patent Document 1, voltage dividing resistors R101 and R102, a reference voltage source 102 having a reference voltage Vref, and switches SW101 and SW102.

In the comparator circuit configured as described above, when the manufacturing shipment mode is set, the switch SW101 is turned off and the switch SW102 is turned on. At this time, a predetermined bias voltage is applied to the inverting input terminal of the comparator circuit, resulting in an input potential difference of the comparator. That is, the NBTI occurs in a state where the operation of the reference voltage circuit is stopped.

In order to solve this problem, the present inventors have devised comparator circuits according to the following embodiments. It is noted that an example of a comparator using PMOS transistors as a differential pair used in FIG. 6 and the like will be described below with reference to FIG. 7.

FIG. 7 is a circuit diagram illustrating a configuration of a comparator circuit according to a comparison example disclosed in Patent Document 1. The comparator circuit of FIG. 7 is, for example, an abnormal voltage detector circuit that detects a case where the input voltage Vin is lower than the reference voltage Vref as an abnormality. The comparator circuit 201 includes PMOS transistors M1 and M2 configuring a differential pair. The sources of the PMOS transistors M1 and M2 are commonly connected to one end of a current source 212. Another end of the current source 212 is connected to a power supply line 211. The gate of the PMOS transistor M1 is connected to an input terminal T201 to which the input voltage Vin is applied via an NMOS transistor M5. The gate of the PMOS transistor M2 is connected to a reference voltage source 203 that supplies the reference voltage Vref.

In the NMOS transistor M5, a source-drain path, which is a main current path, is connected between the input terminal T201 and the gate of the PMOS transistor M1. The drain of the NMOS transistor M5 is connected to the input terminal T201, and the source is connected to the gate of the PMOS transistor M1. A bias voltage V1 is applied to the gate of the NMOS transistor M5 by a bias circuit 220.

The bias circuit 220 includes a diode-connected NMOS transistor M6. The drain and the gate of the NMOS transistor M6 are connected to one end of the constant current source 221, and the source is connected to the reference voltage source 203. Another end of the constant current source 221 is connected to the power supply line 211. The gate voltage of the NMOS transistor M6 is higher than the reference voltage Vref by a gate-source voltage Vgs of the NMOS transistor M6. Therefore, the bias voltage V1 becomes Vref+Vgs.

An NMOS transistor M3 to which a source-drain path as a main current path is connected is provided between the drain of the PMOS transistor M1 and the ground. The NMOS transistor M3 forms a diode connection in which the drain and the gate are commonly connected. An NMOS transistor M4 to which a source-drain path as a main current path is connected is provided between the drain of the PMOS transistor M2 and the ground. The gate of the NMOS transistor M4 is connected to the gate of the NMOS transistor M3. The NMOS transistors M3 and M4 configure a current mirror circuit. The connection point between the PMOS transistor M2 and the NMOS transistor M4 is connected to an output terminal T202, and the output terminal T202 outputs the output voltage Vout1.

In the comparator circuit according to the conventional example of FIG. 7, an input potential difference of the comparator circuit is likely to occur, and occurrence of NBTI cannot be suppressed in a state where the operation of the reference voltage circuit is stopped. In particular, it is conceivable that a protection circuit of a lithium battery is in a standby state for a long time in a factory shipment mode or the like, and at that time, the reference voltage circuit is stopped and the NBTI occurs.

### FIRST EMBODIMENT

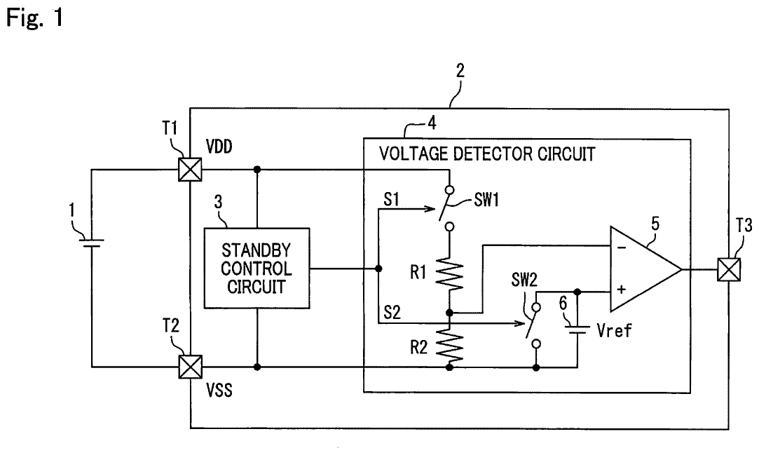

FIG. 1 is a circuit diagram illustrating a configuration example of a comparator circuit according to a first embodiment. A comparator circuit 2 of FIG. 1 is a circuit for detecting an abnormal voltage of a secondary battery 1 such as a nickel ion battery, and has terminals T1 to T3, and includes a standby control circuit 3, and a voltage detector circuit 4. In this case, the voltage detector circuit 4 includes voltage dividing resistors R1 and R2, switches SW1 and SW2, a reference voltage source 6 having a reference voltage Vref, and a comparator 5 using PMOS transistors as a differential pair.

Referring to FIG. 1, the secondary battery 1 is connected between the terminals T1 and T2, and the standby control circuit 3 is connected. The terminal T1 is connected to the terminal T2 via the switch SW1 and the voltage dividing resistors R1 and R2. The battery voltage from the secondary battery 1 is divided by the voltage dividing resistors R1 and R2 via the switch SW1, and the divided voltage is applied to the inverting input terminal of the comparator 5. The reference voltage Vref of the reference voltage source 6 is applied to the non-inverting input terminal of the comparator 5.

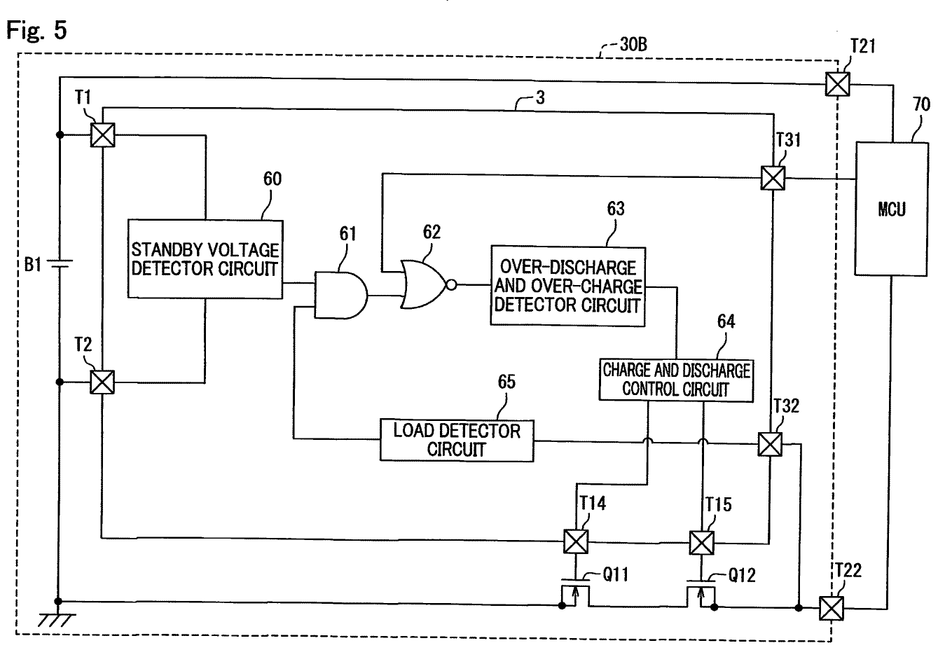

Referring to FIG. 1, the standby control circuit 3 is, for example, a circuit described later in a fifth embodiment of FIG. 5, and detects, for example, a standby state (circuit operation stop state) of the shipping mode at the time of manufacturing shipment under the following conditions:
(1) the case where a voltage between both ends of the secondary battery 1 is equal to or lower than a predetermined standby voltage and a load detector circuit detects that a predetermined load is connected between external load terminals; or
(2) the case where a standby control signal is input to an external input terminal of a micro-controller unit (MCU) (see FIG. 5) that is a system controller using the comparator circuit 2.

When detecting the standby state, the standby control circuit 3 generates control signals S1 and S2 for switching over from on to off with the switch SW1 and from off to on with the switch SW2, and outputs the control signals S1 and S2 to the control terminals of the switches SW1 and SW2. As a result, the input terminal pair of the comparator 5 is short-circuited via the resistor R2, so that the respective input voltages of the comparator 5 become equal.

According to the comparator circuit 2 configured as described above, the standby control circuit 3 detects the standby state, and controls the input voltages of the comparator 5 to be equal, that is, the input voltage difference to be zero according to the control signals S1 and S2. As a result, it is possible to suppress characteristic deterioration due to NBTI in the PMOS transistors which is a differential pair in the comparator 5.

### SECOND EMBODIMENT

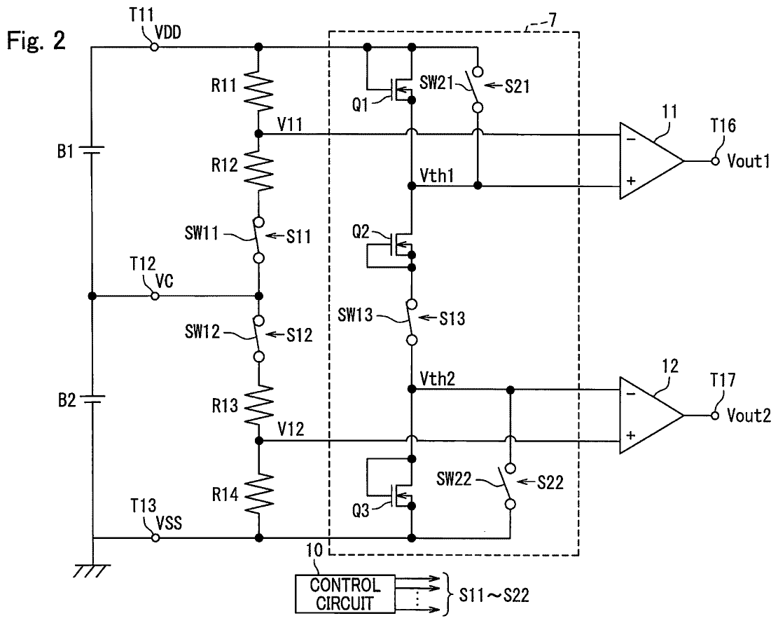

FIG. 2 is a circuit diagram illustrating a configuration example of a comparator circuit according to a second embodiment. The comparator circuit of FIG. 2 is an abnormal voltage detector circuit for detecting an abnormal voltage of secondary batteries B1 and B2, and has terminals T11 to T17, and includes voltage dividing resistors R11, R12, R13, and R14, NMOS transistors Q1, Q2, and Q3, switches SW11, SW12, SW13, SW21, and SW22, comparators 11 and 12 using PMOS transistors as a differential pair, and a control circuit 10. In this case, the NMOS transistors Q1 to Q3 and the switches SW13 to SW22 configure a reference voltage circuit 7. The control circuit 10 is a circuit that controls the operation of the comparator circuit, generates control signals S11 to S22 for controlling on or off operations of the switches SW11 to SW22, and outputs the control signals S11 to S22 to the control terminals of the switches SW11 to SW22.

Referring to FIG. 2, the secondary batteries B1 and B2 are connected in series, the positive electrode of the secondary battery B1 is connected to the terminal T11, the negative electrode of the secondary battery B1 and the positive electrode of the secondary battery B2 are connected to the terminal T12, and the negative electrode of the secondary battery B2 is connected to the terminal T13 and grounded.

The terminal T11 of the power supply voltage VDD is connected to the terminal T13 of the ground voltage VSS via the voltage dividing resistors R11 and R12, the switches SW11 and SW12, and the voltage dividing resistors R13 and R14. In this case, the connection point between the switch SW11 and the switch SW12 is connected to the terminal T12 of the intermediate voltage VC. In addition, the terminal T11 is connected to the terminal T13 via the drain and the source of the diode-connected NMOS transistor Q1, the drain and the source of the diode-connected NMOS transistor Q2, the switch SW13, and the drain and the source of the diode-connected NMOS transistor Q3. Further, the switch SW21 is connected in parallel with the NMOS transistor Q1, and the switch SW22 is connected in parallel with the NMOS transistor Q3.

The voltage V11 divided by the voltage dividing resistors R11 and R12 is applied to the inverting input terminal of the comparator 11, and the voltage V12 divided by the voltage dividing resistors R13 and R14 is applied to the non-inverting input terminal of the comparator 12. The voltage Vth1 at the connection point between the NMOS transistors Q1 and Q2 is applied to the non-inverting input terminal of the comparator 11, and the voltage Vth2 at the connection point between the switch SW13 and the NMOS transistor Q3 is applied to the inverting input terminal of the comparator 12. The output terminal of the comparator 11 is connected to the terminal T16, and the output terminal of the comparator 12 is connected to the terminal T17.

The control circuit 10 controls the switches SW11 to SW13 by outputting a control signal for turning on the switches SW21 to SW22 and turning off the switches SW11 to SW22 when the comparator circuit operates. In addition, the control circuit 10 controls each of the switches SW11 to SW13 by outputting a control signal for turning off the switches SW21 to SW22 and turning on the switches SW11 to SW22 in the standby state.

In the comparator circuit configured as described above, the comparator 11 outputs the abnormal voltage detection signal Vout1 having the H level from the terminal T16 when V11≤Vth1, and the power supply voltage VDD on the high potential side becomes equal to or higher than a predetermined threshold voltage. In addition, the comparator 12 outputs an abnormal voltage detection signal Vout2 having the H level from the terminal T17 when V12>Vth2, and the intermediate voltage VC of the intermediate potential becomes equal to or higher than a predetermined threshold voltage.

In addition, according to the comparator circuit according to the present embodiment, since the switches SW11 to SW13 are turned off and the switches SW21 and SW22 are turned on in the standby state, each input terminal of the comparator 11 is short-circuited via the resistor R11 and set to the power supply voltage VDD, and each input terminal of the comparator 12 is short-circuited via the resistor R14 and set to the ground voltage VSS. That is, the input voltage differences of the two comparators 11 and 12 have the same potential. As a result, it is possible to suppress characteristic deterioration due to NBTI in the PMOS transistors of a differential pair in the comparators 11 and 12.

### THIRD EMBODIMENT

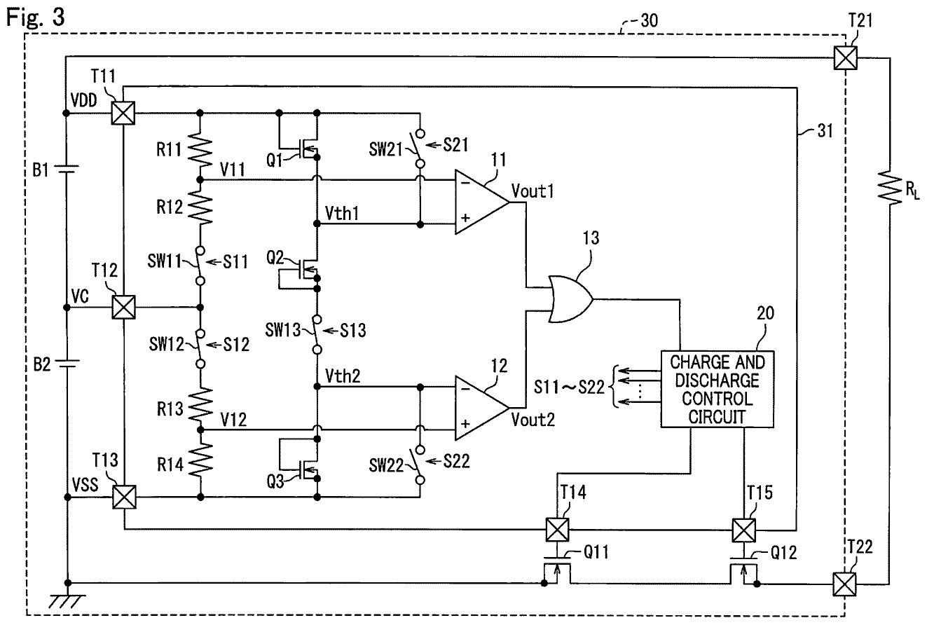

FIG. 3 is a circuit diagram illustrating a configuration example of a power supply apparatus using a comparator circuit according to a third embodiment. The comparator circuit of FIG. 3 is an over-discharge and over-charge detector circuit 31 using the comparator circuit of FIG. 2, has terminals T11 to T22, and includes an OR gate 13, a charge and discharge control circuit 20, and NMOS transistors Q11 and Q12 which are charge and discharge control switch elements, in addition to the comparator circuit of FIG. 2. In addition, secondary batteries B1 and B2 and the over-discharge and over-charge detector circuit 31 configure a power supply apparatus 30. The differences from FIG. 2 will be described below.

Referring to FIG. 3, the series voltage of the secondary batteries B1 and B2 is output to the load resistance RL via the NMOS transistors Q11 and Q12 and the terminals T21 and T22. The comparator 11 outputs an abnormal voltage detection signal Vout1 to the charge and discharge control circuit 20 via the OR gate 13, and the comparator 12 outputs the abnormal voltage detection signal Vout2 to the charge and discharge control circuit 20 via the OR gate 13.

The charge and discharge control circuit 20 performs charge and discharge control processing as follows, and performs a characteristic degradation suppression process by NBTI on the comparator circuit in the standby state.

The comparator 11 compares the divided voltage V11 (divided voltage from the voltage of the secondary battery B1 when the switch SW11 is turned on) of the voltage dividing resistors R11 and R12 with the reference voltage Vth1 for the power supply voltage VDD, detects that the power supply voltage VDD, which is the cell voltage, has become equal to or higher than a predetermined threshold when V11≤Vth1, and outputs the abnormal voltage detection signal Vout1 having the H level. In addition, the comparator 12 compares the divided voltage V12 (divided voltage from the voltage of the secondary battery B2 when the switch SW12 is on) of the voltage dividing resistors R13 and R14 with the reference voltage Vth2 for the intermediate voltage VC, detects that the intermediate voltage VC has become equal to or higher than a predetermined threshold when V12>Vth2, and outputs an abnormal voltage detection signal Vout2 having the H level. When either the abnormal voltage detection signal Vout1 or Vout2 becomes the H level, the H level signal is input from the OR gate 13 to the charge and discharge control circuit 20, and in response to this, the charge control is performed by outputting the control signal having the L level to the gates of the NMOS transistors Q11 and Q12, and the abnormal charge can be stopped.

Since the over-discharge and over-charge detector circuit 31 using the comparator circuit configured as described above uses the comparator of FIG. 2, it is possible to suppress characteristic deterioration due to NBTI in the PMOS transistors of a differential pair in the comparators 11 and 12.

### FOURTH EMBODIMENT

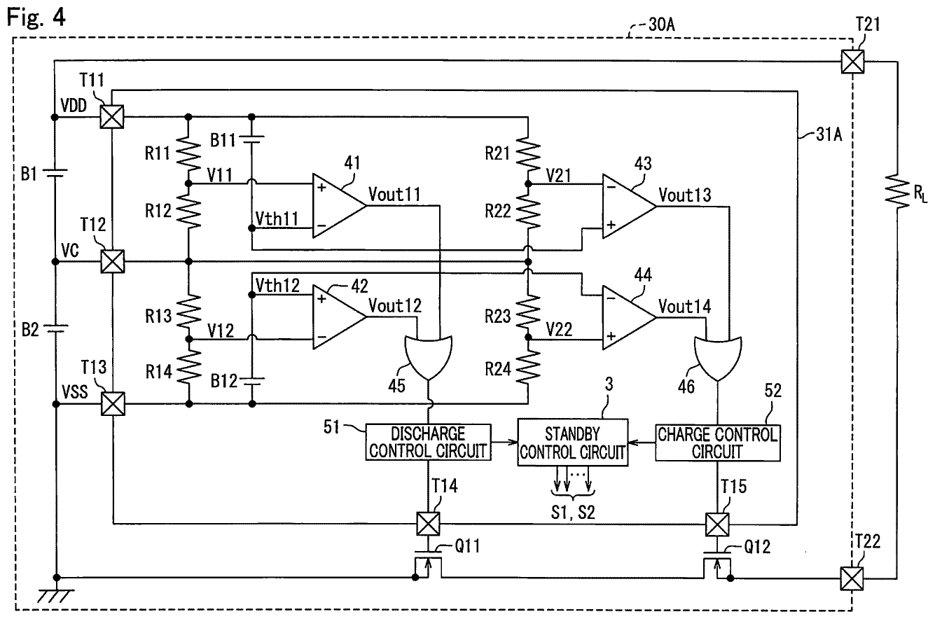

FIG. 4 is a circuit diagram illustrating a configuration example of a power supply apparatus using a comparator circuit according to a fourth embodiment. The comparator circuit of FIG. 4 is an over-discharge and over-charge detector circuit 31A using the comparator circuit of FIG. 1. The over-discharge and over-charge detector circuit 31A has terminals T11 to T15, and includes voltage dividing resistors R11, R12, R13, R14, R21, R22, R23, and R24, reference voltage sources B11 and B12, a comparator circuits 41 to 44 using the comparator circuit of FIG. 1, OR gates 45 and 46, a standby control circuit 3, a discharge control circuit 51, and a charge control circuit 52. In addition, secondary batteries B1 and B2 and the over-discharge and over-charge detector circuit 31A configure a power supply apparatus 30A. Hereinafter, the differences from FIGS. 2 and 3 will be described.

Referring to FIG. 4, a divided voltage V11 obtained by dividing the battery voltage of the secondary battery B1 by the voltage dividing resistors R11 and R12 is applied to the non-inverting input terminal of the comparator circuit 41, and a reference voltage Vth11 of the reference voltage source B11 is applied to the inverting input terminal of the comparator circuit 41. In addition, a divided voltage V12 obtained by dividing the battery voltage of the secondary battery B1 by the voltage dividing resistors R13 and R14 is applied to the non-inverting input terminal of the comparator circuit 42, and a reference voltage Vth 12 of the reference voltage source B12 is applied to the inverting input terminal of the comparator circuit 42. Further, a divided voltage V21 (<V11) obtained by dividing the battery voltage of the secondary battery B1 by the voltage dividing resistors R21 and R22 is applied to the inverting input terminal of the comparator circuit 43, and the reference voltage Vth11 of the reference voltage source B11 is applied to the non-inverting input terminal of the comparator circuit 43. In addition, a divided voltage V22 (<V12) obtained by dividing the battery voltage of the secondary battery B2 by the voltage dividing resistors R23 and R24 is applied to the non-inverting input terminal of the comparator circuit 44, and the reference voltage Vth 12 of the reference voltage source B11 is applied to the inverting input terminal of the comparator circuit 44.

The abnormal voltage detection signal Vout11 from the comparator circuit 41 is input to the discharge control circuit 51 via the OR gate 45, and the abnormal voltage detection signal Vout12 from the comparator circuit 42 is input to the discharge control circuit 51 via the OR gate 45. In addition, the abnormal voltage detection signal Vout13 from the comparator circuit 43 is input to the charge control circuit 52 via the OR gate 46, and the abnormal voltage detection signal Vout14 from the comparator circuit 44 is input to the charge control circuit 52 via the OR gate 46. Further, the standby control circuit 3 generates control signals S1 and S2 based on signals from the discharge control circuit 51 and the charge control circuit 52, and outputs the control signals S1 and S2 to the comparator circuit 41 to 44.

In the over-discharge and over-charge detector circuit 31A configured as described above, when at least one of the abnormal voltage detection signals Vout11 and Vout12 becomes the H level, the H level signal is input to the discharge control circuit 51, and in response to this, the discharge control circuit 51 applies the L level signal to the gate of the NMOS transistor Q11 to turn off the NMOS transistor Q11. As a result, discharge control is performed, and abnormal discharge is stopped. In addition, when at least one of the abnormal voltage detection signals Vout13 and Vout14 becomes the H level, the H level signal is input to the charge control circuit 52, and in response to this, the charge control circuit 52 applies the L level signal to the gate of the NMOS transistor Q12 to turn off the NMOS transistor Q12. As a result, charge control is performed, and abnormal charge is stopped.

Therefore, the over-discharge and over-charge detector circuit 31A in FIG. 4 can perform the above-described discharge control and charge control, and includes the comparator circuits 41 to 44 using the comparator circuit in FIG. 1, so that it is possible to suppress characteristic deterioration due to NBTI in the PMOS transistors of a differential pair in the comparator circuit 41 to 41.

### FIFTH EMBODIMENT

FIG. 5 is a circuit diagram illustrating a configuration example of a power supply apparatus using a standby control circuit 3 according to a fifth embodiment. The standby control circuit 3 in FIG. 5 includes a standby voltage detector circuit 60, an AND gate 61, an OR gate with inversion output 62, an over-discharge and over-charge detector circuit 63, a charge and discharge control circuit 64, and a load detector circuit 65.

Referring to FIG. 5, in a case where the standby voltage detector circuit 60 detects that a voltage of a secondary battery B1 is equal to or lower than a predetermined standby voltage and the load detector circuit 65 detects that a load is connected between terminals T21 and T22, for example, by current detection, or in a case where a standby control signal is input to an external input terminal from a MCU 70 or the like that receives power supply from the secondary battery B1, an L level signal is input to the over-discharge and over-charge detector circuit 63, and the state transitions to the standby state. It is noted that the charge and discharge control circuit 64 operates similarly to the charge and discharge control circuit 20 of FIG. 3 or the control circuit 10 of FIG. 2.

### MODIFIED EMBODIMENTS

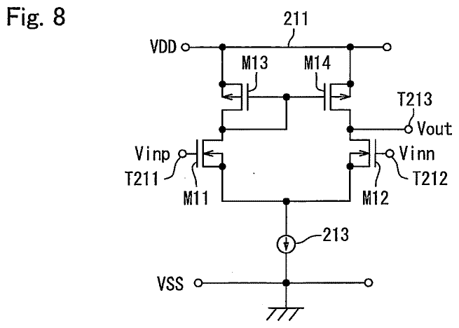

The above embodiments disclose a circuit that can suppress the occurrence of NBTI in a comparator circuit using a PMOS transistors as a differential pair without depending on an input potential difference of the comparator circuit. However, the present invention is not limited thereto, and in a comparator circuit using NMOS transistors as a differential pair, a circuit that can suppress the occurrence of PBTI without depending on an input potential difference of the comparator circuit can be similarly configured (FIG. 8). For example, the comparator circuit includes a control circuit that controls voltages of two input terminals of the comparator to be equal to each other in a standby state that is a circuit operation stop state of the comparator circuit. This makes it possible to suppress the occurrence of PBTI.

FIG. 8 is a circuit diagram showing a known configuration of a comparator circuit according to a comparison example. Referring to FIG. 8, the comparator circuit has input terminals T211 and T212 and an output terminal T213, and includes NMOS transistors M11 and M12 used as a differential pair, PMOS transistors M13 and M14 configuring a current mirror circuit, and a constant current source 213 between a power supply line 211 and the ground.

### INDUSTRIAL APPLICABILITY

As mentioned in detail, according to the comparator circuit of the present invention, in the comparator circuit using the PMOS transistor or the NMOS transistor as the differential pair, it is possible to suppress the occurrence of NBTI or PBTI without depending on the input potential difference of the comparator circuit.

### REFERENCE SIGNS LIST

1, B1, and B2 Secondary battery
2 Comparator circuit
3 Standby control circuit
4 Voltage detector circuit
5 Comparator
6 Reference voltage source
7 Reference voltage circuit
10 Control circuit
11, and 12 Comparator
13 OR gate
20 Charge and discharge control circuit
30, 30A, and 30B Power supply apparatus
31, and 31A Over-discharge and over-charge detector circuit
41 to 44 Comparator circuit
45, and 46 OR gate
51 Discharge control circuit
52 Charge control circuit
60 Standby voltage detector circuit
61 AND gate
62 OR gate with inversion output
63 Over-discharge and over-charge detector circuit
64 Charge and discharge control circuit
65 Load detector circuit
70 MCU
101 Comparator
102 Reference voltage source
201 Comparator circuit
203 Reference voltage source
211 Power supply line
212 Constant current source
213 Constant current source
220 Bias circuit
221 Constant current source
B1, and B2 Secondary battery
B11, and B12 Reference voltage source
M1, M2, M13, and M14 PMOS transistor
M3, M4, M5, M6, M11, M12, and Q1 to Q12 NMOS transistor
R1 to R14, R101, and R102 Voltage dividing resistor
RL Load resistor
SW1 to SW22 Switch
T1 to T213 Terminal

1. A comparator circuit comprising a comparator for detecting an abnormal voltage of a secondary battery, the comparator using a PMOS transistor or an NMOS transistor as a differential pair, the comparator circuit comprising:
a control circuit configured to control voltages at two input terminals of the comparator to be equal to each other in a standby state that is a circuit operation stop state of the comparator circuit.

2. The comparator circuit as claimed in claim 1, further comprising:
a pair of voltage dividing resistors configured to divide a voltage of the secondary battery, and output a divided voltage to an inverting input terminal of the comparator; and
a reference voltage source configured to generate a predetermined reference voltage, and output the reference voltage to a non-inverting input terminal of the comparator,
wherein the control circuit is configured to stop voltage supply from the secondary battery to the voltage dividing resistors, and control the voltages at two input terminals of the comparator are equal to each other, in the standby state.

3. The comparator circuit as claimed in claim 2,
wherein the secondary battery includes first and second secondary batteries connected in series to each other,
wherein the comparator includes first and second comparators,
wherein the voltage dividing resistors include first and second voltage dividing resistors,
wherein the reference voltage source includes first and second reference voltage sources,
wherein a voltage obtained by dividing a voltage of the first secondary battery by the first voltage dividing resistor is input to an inverting input terminal of the first comparator,
wherein a reference voltage of the first reference voltage source is input to a non-inverting input terminal of the first comparator,
wherein a voltage obtained by dividing a voltage of the second secondary battery by the second voltage dividing resistor is input to an inverting input terminal of the second comparator,
wherein a reference voltage of the second reference voltage source is input to a non-inverting input terminal of the second comparator, and
wherein, in the standby state, the control circuit is configured to stop voltage supply from the first and second secondary batteries to the first and second voltage dividing resistors, respectively, and control the voltages at two input terminals of the first and second comparators to be equal to each other.

4. A power supply apparatus comprising the comparator circuit as claimed claim 1,
wherein the control circuit is a charge and discharge control circuit.

5. A power supply apparatus comprising:
a first comparator circuit that is configured to have a same configuration as the comparator circuit of claim 1, wherein the secondary battery includes first and second secondary batteries connected in series with each other, and the first comparator circuit is configured to detect a discharge abnormal voltage related to the first secondary battery;
a second comparator circuit that is configured to have a same configuration as the comparator circuit and is configured to detect a discharge abnormal voltage related to the second secondary battery;
a third comparator circuit that is configured to have a same configuration as the comparator circuit and is configured to detect a charge abnormal voltage related to the first secondary battery;
a fourth comparator circuit that is configured to have a same configuration as the comparator circuit and is configured to detect a charge abnormal voltage related to the second secondary battery;
a discharge control circuit configured to control discharge based on an abnormal voltage detection signal from the first comparator circuit and an abnormal voltage detection signal from the second comparator circuit; and
a charge control circuit configured to control charge based on an abnormal voltage detection signal from the third comparator circuit and an abnormal voltage detection signal from the fourth comparator circuit.
